(19) United States
(12) Patent Application Publication
(10) Pub. No.: US 2007/0145238 A1
(43) Pub. Date: Jun. 28, 2007

(54) Method for Manufacturing Mask and CMOS Image Sensor

(76) Inventors: Yeon Ah Shim, Hampyeong-gun (KR); Kee Ho Kim, Seongnam-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/611,186

(22) Filed: Dec. 15, 2006

(30) Foreign Application Priority Data
Dec. 28, 2005 (KR) 10-2005-0132729

(51) Int. Cl. H01L 27/00

(52) U.S. Cl. 250/208.1

(57) ABSTRACT

A mask for forming a microlens pattern and a CMOS image sensor manufactured using the mask for forming a microlens pattern is provided. The mask includes a transparent substrate, a plurality of light-blocking layers, and a dummy pattern. The plurality of light-blocking layers are formed on the transparent substrate to define microlens regions of an image sensor, and the dummy pattern is formed between the plurality of light-blocking layers. The dummy pattern can be formed between corners of four adjacent light-blocking layers.

### RELATED APPLICATION(S)

This application claims the benefit under 35 USC §119(e) of Korean Patent Application No. 10-2005-0132729 filed Dec. 28, 2005, which is hereby incorporated by reference in its entirety.

### FIELD OF THE INVENTION

The present invention relates to a method for manufacturing a mask for forming a microlens pattern and a complementary metal oxide semiconductor (CMOS) image sensor using the mask.

### BACKGROUND OF THE INVENTION

In general, an image sensor is a semiconductor device for converting an optical image into an electrical signal, and is roughly classified as a charge coupled device (CCD) image sensor or a complementary metal oxide semiconductor (CMOS) image sensor.

The CMOS image sensor includes a photodiode unit for detecting incident light and converting the detected light into an electric signal, and a CMOS logic circuit for processing the electric signal to provide corresponding data. As the amount of light received in the photodiode increases, the photosensitivity of the image sensor increases.

Various methods are employed to increase the photo sensitivity of an image sensor. In one method, a technology is used for increasing the ratio (a fill factor) of an area occupied by a photodiode to the total area of the image sensor. In another method, a light condensing technology is used for changing an optical path of light incident on an area outside a photodiode to the photodiode.

A typical example of a light condensing technology is to form microlenses. According to this technology, convex microlenses are formed of a material having excellent light transmittance on an upper surface of a photodiode region to refract incident light such that a larger amount of light is illuminated to the photodiode region.

In this case, light parallel to an optical axis of the microlens is refracted by the microlens to form a focus on a predetermined location on the optical axis.

In a CMOS image sensor, because the number of photodiodes receiving an image determines resolution in manufacturing a device for an image sensor, a pixel is miniaturized as the photodiode is miniaturized.

Color filters are used to form a color filter layer of primary colors or complementary colors in order to achieve color separation. A primary color filter layer includes red, green, and blue color filters. A complementary color filter layer includes cyan, yellow, and magenta color filters. The color filter layer is formed on-chip to separate colors and reproduce colors.

In order to efficiently utilize incident light and make maximum use of the incident light, a microlens is formed to increase a light condensing efficiency. Typically, a microlens is formed by performing thermal reflow on a photoresist.

However, when reflow is performed to form a microlens having an increased maximum such that it is capable of condensing a larger amount of light, a bridge may be generated between adjacent microlenses. Therefore, a critical dimension needs to be maintained to some extent.

CMOS image sensors having the above-described characteristics are generally classified as 3T type, 4T type, or 5T type CMOS image sensors depending on the number of transistors formed in a unit pixel. The 3T type CMOS image sensor includes one photodiode and three transistors. The 4T type CMOS image sensor includes one photodiode and four transistors. An equivalent circuit and lay-out of a unit pixel of a 3T type CMOS image sensor is described below.

FIG. 1 is an equivalent circuit diagram of a 3T type CMOS image sensor according to the related art, and FIG. 2 is a lay-out diagram illustrating a unit pixel of a 3T type CMOS image sensor according to the related art.

Referring to FIG. 1, the 3T type CMOS image sensor includes one photodiode (PD) and three nMOS transistors T1, T2, and T3. A cathode of the PD is connected to the drain of the first nMOS transistor T1 and the gate of the second nMOS transistor T2.

Also, sources of the first and second nMOS transistors T1 and T2 are connected to a power line through which a reference voltage VR is supplied. The gate of the first nMOS transistor T1 is connected to a reset line through which a reset signal RST is supplied.

Also, the source of the third nMOS transistor T3 is connected to the drain of the second nMOS transistor. The drain of the third nMOS transistor T3 is connected to a reading circuit via a signal line, and the gate of the third nMOS transistor T3 is connected to a row selection line through which a selection signal SLCT is supplied.

Therefore, the first nMOS transistor T1 is called a reset transistor Rx, the second nMOS transistor T2 is called a drive transistor Dx, and the third nMOS transistor T3 is called a selection transistor Sx.

Referring to FIG. 2, a unit pixel of the related art 3T type CMOS image sensor includes an active region 10. One photodiode (PD) 20 is formed on a wide portion of the active region 10, and gate electrodes 120, 130, and 140 of three transistors are formed on the other portion of the active region 10.

That is, a reset transistor Rx is formed by the first gate electrode 120, a drive transistor Dx is formed by the second gate electrode 130, and a selection transistor Sx is formed by the third gate electrode 140.

Here, impurity ions are implanted in the active region 10 by the gate electrodes, but not below each gate electrode 120, 130, and 140, so that source/drain regions for each transistor are formed.

A power voltage Vdd can be applied to source/drain regions between the reset transistor Rx and the drive transistor Dx, and the source/drain regions on one side of the selection transistor SX can be connected to a reading circuit.

Though not shown in FIG. 2, the gate electrodes 120, 130, and 140 are connected to respective signal lines. Each of the signal lines has a pad at one end and is connected to an external driving circuit.

A CMOS image sensor according to the related art will be descried below with reference to the accompanying drawings.

FIG. 3 is a cross-sectional view of a CMOS image sensor according to the related art.

Referring to FIG. 3, the CMOS image sensor includes one or more photodiodes (PDs) 12 formed in a semiconductor substrate 11 to generate charge using the amount of incident light; an interlayer insulating layer 13 formed on an entire surface of the semiconductor substrate 11 including the PDs 12; a color filter layer 14 including red (R), green (G), and blue (B) color filters each being formed on the interlayer insulating layer 13 and passing light in a predetermined wavelength band; an overcoat layer 15 formed on an entire surface of the semiconductor substrate 11 including the color filter layer 14; and microlenses 16 formed in a convex shape having a predetermined curvature on the overcoat layer 15 to transmit light through a corresponding color filter and condense the light to the PD 12.

As the image sensor is miniaturized and achieves higher resolution, more pixels are formed per unit area. In addition, as the size of a pixel reduces, sizes of the color filter and the microlens formed on-chip also reduce. Since sensitivity of an image sensor reduces due to the reduction of the area of a PD region that receives light as the size of a unit pixel is reduced, a microlens is typically formed in order to compensate for the reduced sensitivity.

The microlens is formed by setting the thickness of a photoresist suitably for a pixel size and length of a device, coating a substrate with the photoresist to the set thickness, forming a pattern using exposure and development processes, and applying thermal energy on the pattern to reflow the pattern.

The above-mentioned method for forming a microlens according to the related art is described below in detail.

FIG. 4 is a front view of a mask for forming a microlens according to the related art, and FIG. 5 is a plan view of a photoresist pattern patterned using the mask of FIG. 4.

Referring to FIG. 4, a mask for forming a microlens according to the related art includes light-blocking layers 22 formed on a portion of a transparent substrate 21 that corresponds to a unit cell of the CMOS image sensor. Like each unit cell, the light-blocking layers 22 define a microlens region in a quadrangular shape.

Because unit cells of the CMOS image sensor are arranged in a matrix, the light-blocking layers 22 also have a quadrangular shape and are arranged in a matrix. The light-blocking layers 22 block off light during the exposure process while the other regions transmit light.

Typically, to form a microlens according to the related art, an overcoat layer 15 is formed on a substrate, and a photoresist layer is coated on the overcoat layer in order to form the microlens 16 as shown in FIG. 3.

Then, the mask of FIG. 4 is positioned on the photoresist layer, and a photoresist pattern 23 as illustrated in FIG. 5, is formed using photolithography. Like the light-blocking layers 22, the photoresist pattern 23 is disposed in a matrix.

The microlens is formed by applying thermal energy on the photoresist pattern 23 and reflowing the same.

At this point, like the light-blocking layers 22, the photoresist pattern 23 should be formed in a quadrangular shape so that a most ideal photoresist pattern 23 can be formed.

However, as illustrated in FIG. 5, adjacent corners of the photoresist pattern 23 are rounded due to an optical proximity effect, a light interference effect, or resolution.

The corner rounding of the microlens causes crosstalk of a CMOS image sensor and reduces performance of a device.

### BRIEF SUMMARY

Accordingly, the present invention is directed to a method for manufacturing a mask and a complementary metal oxide semiconductor (CMOS) image sensor that addresses and/or substantially obviates one or more problems, limitations, and/or disadvantages of the related art.

An object of the present invention is to provide a mask for manufacturing a microlens for an image sensor having an improved or optimum shape.

Another object of the present invention is to provide a method for manufacturing a CMOS image sensor using the mask.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a mask including: a transparent substrate; a plurality of light-blocking layers formed on the transparent substrate to define microlens regions of an image sensor; and a dummy pattern formed between the plurality of light-blocking layers.

In another aspect of the present invention, there is provided a method for manufacturing a complementary metal oxide semiconductor image sensor, the method including: preparing a mask including a plurality of light-blocking layers for defining patterns of microlenses on a transparent substrate and a dummy pattern formed between the plurality of light-blocking layers; forming a photoresist layer for forming the microlenses on a semiconductor substrate; exposing and developing the photoresist layer using the mask to form a photoresist pattern; and applying thermal energy to the photoresist pattern and reflowing the same to form the microlenses.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is an equivalent circuit diagram of a 3T type CMOS image sensor according to the related art;

FIG. 2 is a lay-out diagram illustrating a unit pixel of a 3T type CMOS image sensor according to the related art;

FIG. 3 is a cross-sectional view of a CMOS image sensor according to the related art;

FIG. 4 is a view illustrating a mask for patterning microlenses of a CMOS image sensor according to the related art;

FIG. 5 is a view illustrating a photoresist pattern for forming microlenses using the mask of FIG. 4;

FIG. 6 is a view illustrating a mask for patterning microlenses of a CMOS image sensor according to an embodiment of the present invention; and

FIG. 7 is a view illustrating a photoresist pattern for forming microlenses using the mask of FIG. 6 according to an embodiment of the present invention.

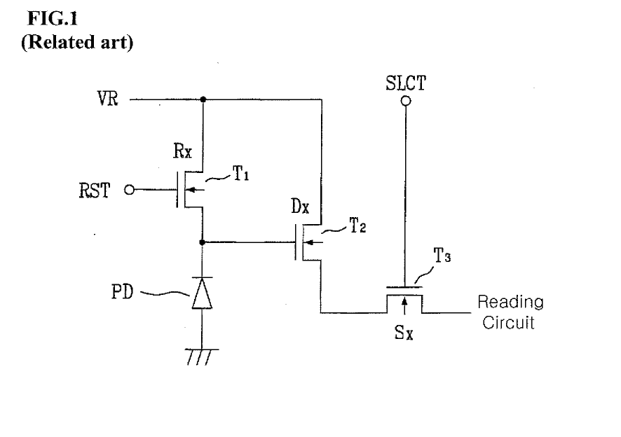

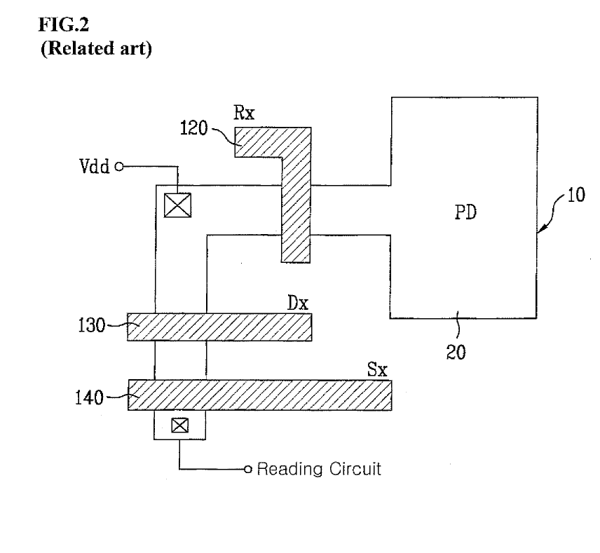

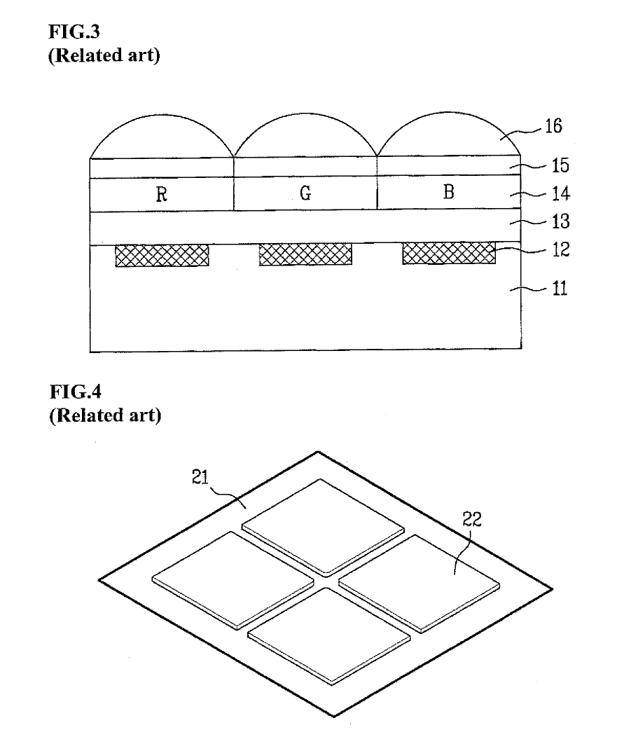

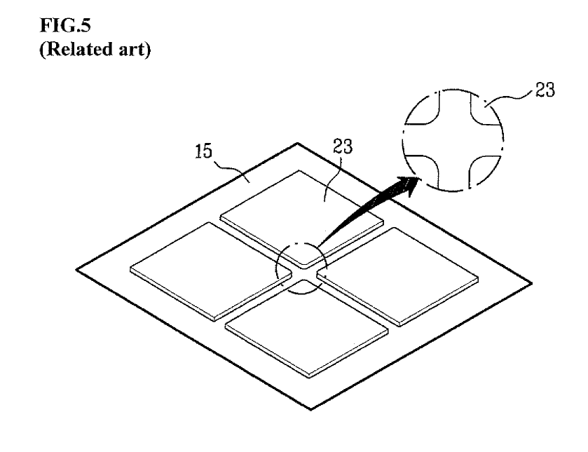

### DETAILED DESCRIPTION OF THE INVENTION

Reference will now be made in detail to the preferred embodiments of the present invention, examples of which are illustrated in the accompanying drawings.

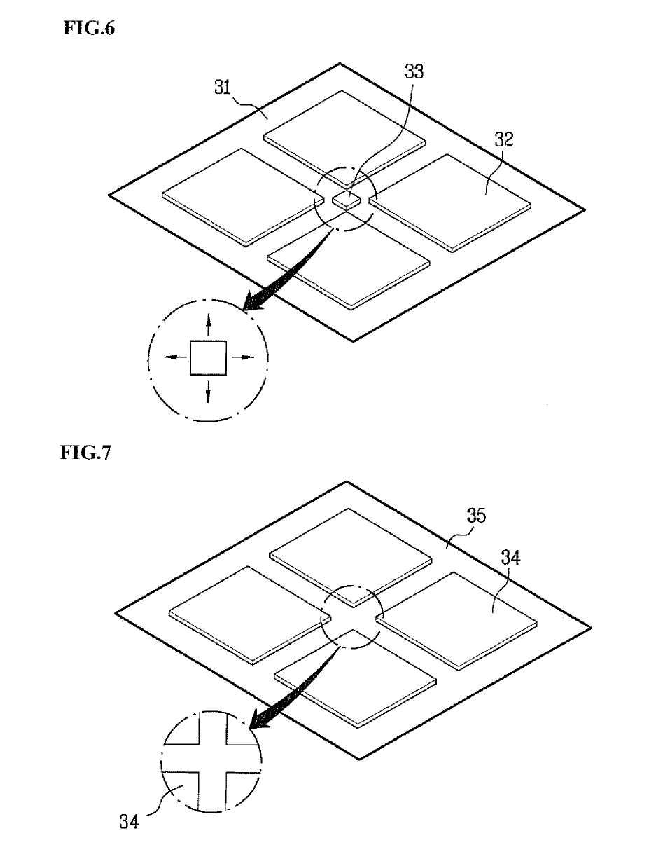

FIG. 6 is a view illustrating a mask for patterning microlenses of a CMOS image sensor according to an embodiment of the present invention, and FIG. 7 is a view illustrating a photoresist pattern for forming microlenses using the mask of FIG. 6 according to the present invention.

Referring to FIGS. 6 and 7, the mask includes a transparent substrate 31, a plurality of light-blocking layers 32 arranged in a matrix on the transparent substrate 31, and a dummy pattern 33 formed between the plurality of light-blocking layers 32.

The size of the dummy pattern 33 can be varied depending on the resolution of the CMOS image sensor or an interval between the light-blocking layers 32.

In addition, although the dummy pattern 33 is shown to have a quadrangular shape in the drawing, the shape of the dummy pattern 33 is not limited thereto. In many embodiments, for example, the dummy pattern 33 can be formed in a circular shape or a polygonal shape.

In a further embodiment, the dummy pattern 33 can be formed of the same material as that of the light-blocking layers 32. In another embodiment, the dummy pattern 33 can be formed of a phase shift material inverting phase of light.

The light-blocking layers 32 can define microlens regions in a quadrangular shape and can be arranged in a matrix.

The light-blocking layers 32 block off light during an exposure process while other portions of the transparent substrate 31 where the light-blocking layers 32 are not formed transmit light.

A method for manufacturing a CMOS image sensor using a mask according to an embodiment of the present invention is described below in detail.

In one embodiment, an overcoat layer 35 can be formed on a substrate having photodiodes (PDs), transistors, metal lines, and a color filter layer. Then, a photoresist layer can be coated on the overcoat layer 35.

A mask, such as the mask of FIG. 6, can be positioned on the photoresist layer, and a photoresist pattern 34 as illustrated in FIG. 7, can be formed using photolithography. Like the light-blocking layers 32, the photoresist pattern 34 is disposed in a matrix.

The microlens can be formed by applying thermal energy on the photoresist pattern 34 and reflowing the same.

In an embodiment, a G-Line or an I-Line photoresist layer having excellent flow ability can be used as the photoresist layer for forming the microlenses. Generally, a material showing photo reaction in a composite wavelength region of a g-line, an h-line, and an I-line can be used.

In a specific embodiment, for example, a photoresist layer where photo reaction occurs in an I-Line wavelength region can be formed to about 0.2-0.5 μm. Then, curing and thermal reflow processes can be performed.

In another embodiment, the photoresist layer for forming the microlenses can be a photoresist layer for KrF or ArF.

Because the dummy pattern 33 is formed between the light-blocking layers 32 of the mask, corner rounding of the photoresist pattern at corner portions of the light-blocking layer 32 caused by an optical proximity effect, a light interference effect, or resolution can be prevented.

As described above, the method for forming a CMOS image sensor according to embodiments of the present invention provides the following effects.

That is, because a dummy pattern is formed at a predetermined portion between light-blocking layers for patterning microlenses in a mask for forming the microlenses, corner rounding of the microlenses can be prevented.

Since the corner rounding of the microlenses can be prevented as described above, crosstalk of the CMOS image sensor can be prevented.

It will be apparent to those skilled in the art that various modifications and variations be made in the present invention. Thus, it is intended that the present invention covers the modifications and variations of this invention provided they come within the scope of the appended claims and their equivalents.

We claim:

1. A mask comprising:
a transparent substrate;
a plurality of light-blocking layers formed on the transparent substrate for defining microlens regions of an image sensor; and
a dummy pattern formed between the plurality of light-blocking layers.

2. The mask according to claim 1, wherein the dummy pattern is formed between corner portions of four adjacent light-blocking layers of the plurality of light-blocking layers.

3. The mask according to claim 1, wherein the dummy pattern has a quadrangular shape.

4. The mask according to claim 1, wherein the dummy pattern has a circular shape.

5. The mask according to claim 1, wherein the dummy pattern has a polygonal shape.

6. The mask according to claim 1, wherein the dummy pattern is formed of the same material as that of the plurality of light-blocking layers.

7. The mask according to claim 1, wherein the dummy pattern is formed of a phase shift material inverting phase of light.

8. A method for manufacturing a complementary metal oxide semiconductor image sensor, the method comprising:
preparing a mask comprising:
a plurality of light-blocking layers for defining a microlens pattern formed on a transparent substrate, and
a dummy pattern formed between the plurality of light-blocking layers on the transparent substrate;
forming a photoresist layer on a semiconductor substrate;
exposing and developing the photoresist layer using the mask to form a photoresist pattern corresponding to the microlens pattern; and
applying thermal energy to the photoresist pattern to reflow the photoresist pattern to form microlenses.

9. The method according to claim 8, wherein the photoresist layer is a g-Line photoresist layer.

10. The method according to claim 8, wherein the photoresist layer is an I-Line photoresist layer.

11. The method according to claim 8, wherein the photoresist layer is a KrF photoresist layer.

12. The method according to claim 8, wherein the photoresist layer is an ArF photoresist layer.

13. The method according to claim 8, wherein the dummy pattern is formed between corner portions of four adjacent light-blocking layers of the plurality of light-blocking layers.

14. The method according to claim 8, wherein the dummy pattern has a quadrangular shape.

15. The method according to claim 8, wherein the dummy pattern has a circular shape.

16. The method according to claim 8, wherein the dummy pattern has a polygonal shape.

17. The method according to claim 8, wherein the dummy pattern is formed of the same material as that of the plurality of light-blocking layers.

18. The method according to claim 8, wherein the dummy pattern is formed of a phase shift material inverting phase of light.
